(19) United States
(12) Patent Application Publication
(10) Pub. No.: US 2018/0006183 A1
(43) Pub. Date: Jan. 4, 2018

(54) DIVISION DEVICE AND DIVISION METHOD THEREOF

(71) Applicant: NEO SOLAR POWER CORP., Hsinchu (TW)

(72) Inventors: Ting-Jui CHEN, Hsinchu (TW); Chia-Hung LIN, Hsinchu (TW); Chun-Ming WU, Hsinchu (TW)

(21) Appl. No.: 15/489,081

(22) Filed: Apr. 17, 2017

(30) Foreign Application Priority Data
Jul. 1, 2016 (TW) 105120924

(51) Int. Cl. H01L 31/18; H01L 31/0203

(52) U.S. Cl. CPC H01L 31/186; H01L 31/0203

(57) ABSTRACT

A division device includes a platform, a withstanding element and a pressure element. The platform has a platform surface. The withstanding element, located on the platform surface, has at least one shrink-top-type withstanding structure protruding from the platform surface and extending along a withstanding line. The shrink-top-type withstanding structure is to withstand the solar cell sheet. The pressure element, located above the platform, has two forcing portions protruding toward the platform. While the solar cell sheet is under dividing, a back surface of the solar cell sheet opposing to the front surface is arranged to face the shrink-top-type withstanding structure by aligning the trench with the withstanding line, and then the two forcing portions are introduced to apply predetermined depression individually onto the two solar cell units, such that the solar cell sheet are divided into the two separate solar cell units.

This application claims the benefit of Taiwan Patent Application Serial No. 105120924, filed Jul. 1, 2016, the subject matter of which is incorporated herein by reference.

### BACKGROUND OF INVENTION

### 1. Field of the Invention

The invention relates to a division device and an accompanying division method thereof, and more particularly to the division device and the division method of the division device that apply a shrink-top-type withstanding structure to withstand a solar cell sheet, and further apply a pressure element to divide forcedly the solar cell sheet into plural smaller solar cell sheets.

### 2. Description of the Prior Art

In the art, solar cells are classified into silicon-based solar cells, thin film solar cells and dye-sensitized solar cells. However, if the solar cell is formed as a solar cell sheet, then the solar cell is generally silicon-based. To meet various demands in dimensions and profiles of the solar cells in a module design, a standard size (156 mm×156 mm for example) of the solar cell sheet is generally applied to be cut into plural smaller solar cell units. For example, also the typical example applied in the following description, a solar cell sheet can be cut or divided into two smaller solar cell units. By dividing a standard size of the solar cell sheet into several pieces with the same dimensions, production efficiency and material utilization can be significantly enhanced.

Currently, a laser machine is applied to perform the cutting to divide the solar cell sheet. Generally speaking, while in performing a division process by a laser machine, a solar cell sheet is transported to the laser machine platform by a conveyer belt. Then, the solar cell sheet is moved to a predetermined area on a platform of the laser machine. With specific laser power, positioning steps and working procedures, the solar cell sheet can then be cut orderly. In general, such a cutting process requires plenty of time upon the working procedures, and thus there is room for improvement upon the current art in cutting the solar cell sheet.

### SUMMARY OF THE INVENTION

In view of the conventional laser cutting for dividing the solar cell sheet includes too many working procedures to save time and to lower the cost, thus the present invention provides a division device and an accompanying division method that apply a shrink-top-type withstanding structure to withstand the solar cell sheet, and a pressure element to divide the solar cell sheet directly. Thereupon, the shortcomings of the conventional method for cutting the solar cell sheet in time-consumption and higher expense can be substantially resolved.

Accordingly, it is the primary object of the present invention to provide a division device for dividing a solar cell sheet into two separate smaller solar cell units. The solar cell sheet has a front surface prepared with a trench extending along a division direction. The two solar cell units are connected at the trench. The division device includes a platform, a withstanding element and a pressure element. The platform has a platform surface. The withstanding element, located on the platform surface, has at least one shrink-top-type withstanding structure protruding from the platform surface and extending along a withstanding line. The shrink-top-type withstanding structure is to withstand the solar cell sheet. The pressure element, located above the platform, has two forcing portions protruding toward the platform. While the solar cell sheet is under dividing, a back surface of the solar cell sheet opposing to the front surface is arranged to face the shrink-top-type withstanding structure by aligning the trench with the withstanding line, and then the two forcing portions are introduced to apply predetermined depression individually onto the two solar cell units, such that the solar cell sheet are divided into the two separate solar cell units.

In one embodiment of the present invention, the shrink-top-type withstanding structure has a shrink top keeping a vertical distance within 0.2-0.4 cm to the platform surface. The shrink top is one of a tip end and a top-shrinking edge extending along the withstanding line. The platform surface further has a platform trench extending along the division direction, so that at least one opening on the platform surface is formed along the platform trench. Also, the withstanding element further has a bottom portion located in the platform trench. In addition, the shrink-top-type withstanding structure extends along the platforms trench and protrudes over the platform surface. Further, a length of the withstanding line is longer than that of the trench of the solar cell sheet.

In one embodiment of the present invention, the solar cell sheet division device further includes at least one constraint element disposed on the platform surface. While the solar cell sheet is under dividing, the at least one constraint element limits the solar cell sheet so as to ensure the trench aligned with the withstanding line. Further, the at least one constraint element is disposed on the platform surface by extending along two limited lines for limiting two corresponding edges of the solar cell sheet. In particular, the constraint element includes two limited strips extending to establish the two limited lines.

In one embodiment of the present invention, the constraint element includes a plurality of limited posts separately disposed along the two limited lines.

In the present invention, the division method applied to the aforesaid division device for dividing a solar cell sheet comprises the steps of: (a) providing the solar cell sheet further having the trench formed on the front surface of the solar cell sheet along the division direction; (b) having the back surface of the solar cell sheet to face the shrink-top-type withstanding structure; (c) having the back surface to contact the shrink-top-type withstanding structure by aligning the trench with the withstanding line defined by the shrink-top-type withstanding structure; and, (d) applying the two forcing portions down to depress the two solar cell units of the solar cell sheet so as to divide the solar cell sheet into the two separate solar cell units.

In one embodiment of the present invention, the solar cell sheet division device further includes at least one constraint element disposed on the platform surface. While in performing step (c) and step (d), the at least one constraint element limits the solar cell sheet so as to ensure the trench aligned with the withstanding line.

In one embodiment of the present invention, in step (c), an alignment device is applied to ensure the trench aligned with the withstanding line. The alignment device is a non-contact optical alignment device, such as a light-emitting device, an image-capturing device, or a combination of the light-emitting device and the image-capturing device.

By providing the division device and the division method in accordance with the present invention, the back surface of the solar cell sheet is introduced to contact directly the shrink-top-type withstanding structure by aligning the trench with the withstanding line, and the pressure element is applied to depress directly and divide perfectly the solar cell sheet, such that tedious working procedures in the conventional division method can be avoided, and thus process time and cost can be substantially reduced.

All these objects are achieved by the division device and the division method thereof described below.

### BRIEF DESCRIPTION OF THE DRAWINGS

The present invention will now be specified with reference to its preferred embodiment illustrated in the drawings, in which:

FIG. 1 is a schematic exploded view of a first embodiment of the division device in accordance with the present invention;

FIG. 2 is a schematic top view of the platform of FIG. 1;

FIG. 3 is a schematic perspective view of a solar cell sheet withstood by the withstanding element of FIG. 1;

FIG. 4 is a schematic front view of FIG. 3;

FIG. 5 shows another state of FIG. 4 with the pressure element moved down to the solar cell sheet;

FIG. 6 shows a further state of FIG. 4 with the pressure element moved back up after the solar cell sheet is divided;

FIG. 7 is a flowchart of a first embodiment of the division method in accordance with the present invention;

FIG. 8 is a schematic top view of a constraint element of a second embodiment of the division device in accordance with the present invention;

FIG. 9 is a schematic top view of a constraint element of a third embodiment of the division device in accordance with the present invention;

FIG. 10 is a schematic top view of a constraint element of a fourth embodiment of the division device in accordance with the present invention; and

FIG. 11 is a schematic top view of a fifth embodiment of the division device in accordance with the present invention.

### DESCRIPTION OF THE PREFERRED EMBODIMENT

The invention disclosed herein is directed to a division device and a division method thereof. In the following description, numerous details are set forth in order to provide a thorough understanding of the present invention. It will be appreciated by one skilled in the art that variations of these specific details are possible while still achieving the results of the present invention. In other instance, well-known components are not described in detail in order not to unnecessarily obscure the present invention.

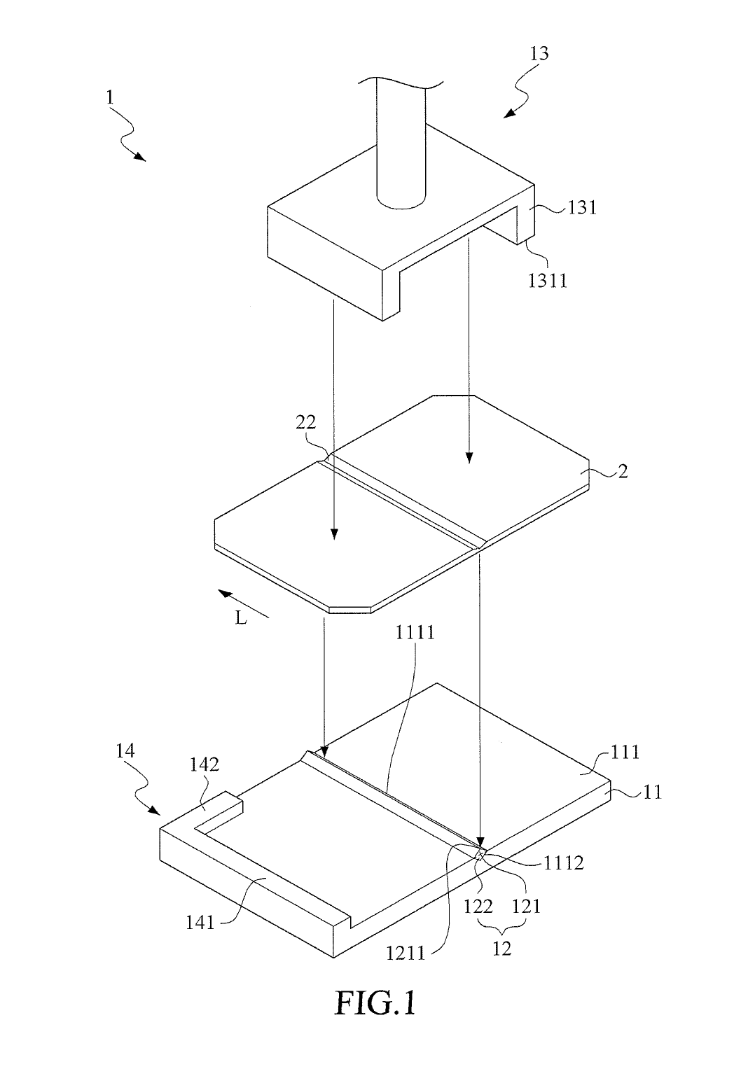

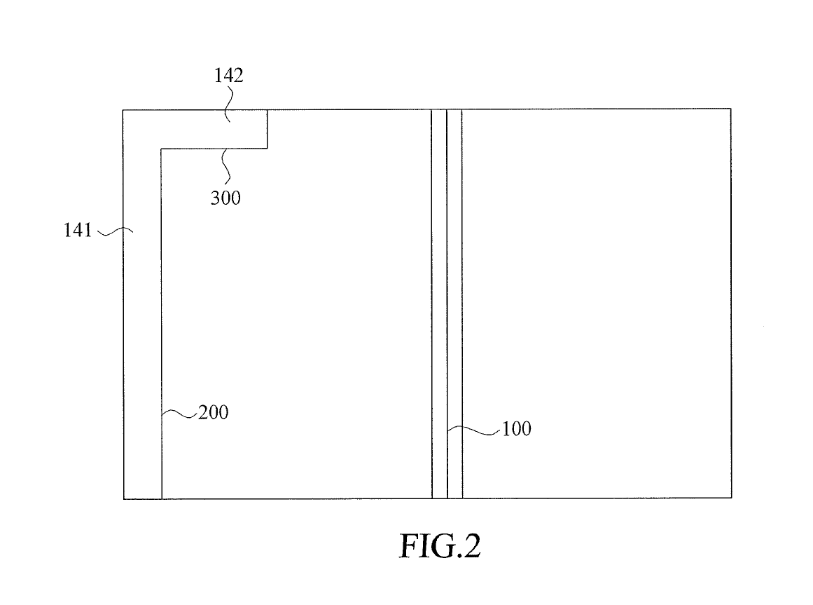

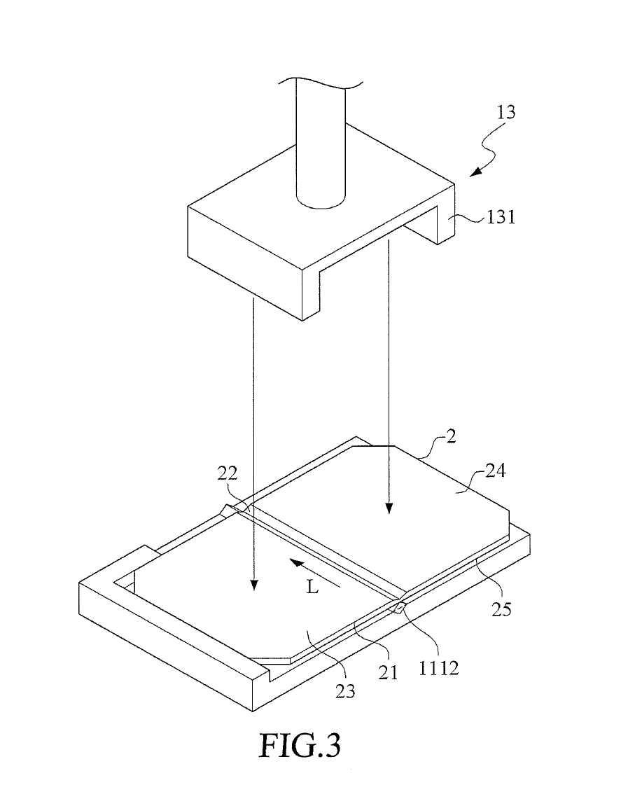

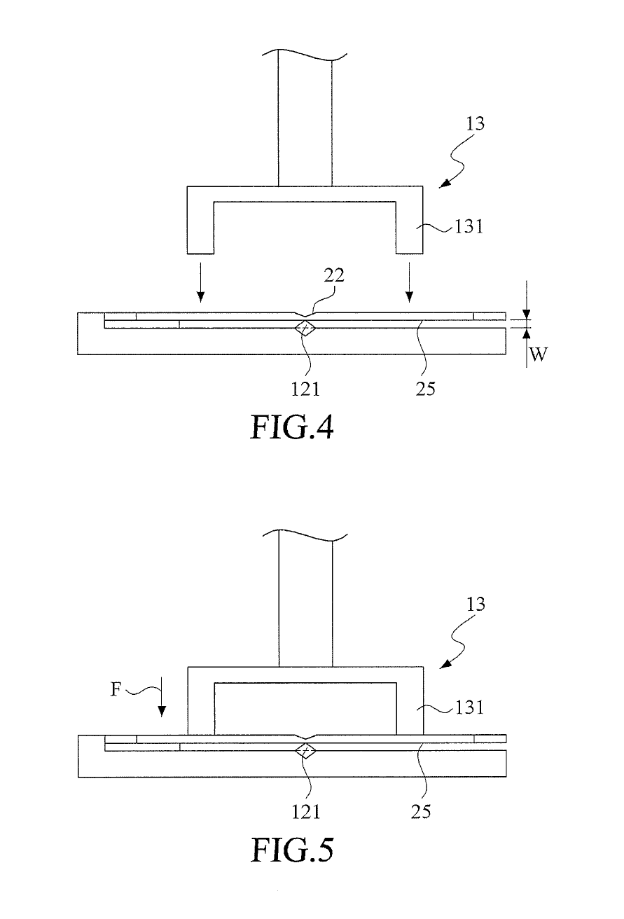

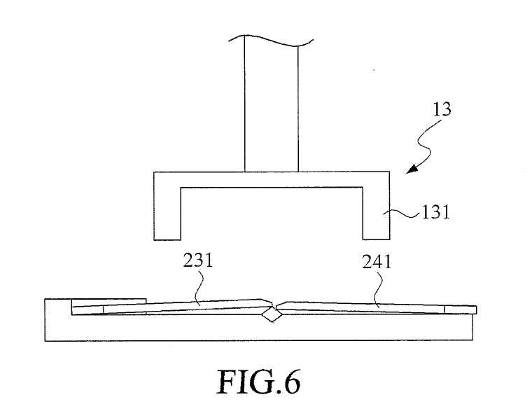

Refer now to FIG. 1 through FIG. 6; where FIG. 1 is a schematic exploded view of a first embodiment of the division device in accordance with the present invention, FIG. 2 is a schematic top view of the platform of FIG. 1, FIG. 3 is a schematic perspective view of a solar cell sheet withstood by the withstanding element of FIG. 1, FIG. 4 is a schematic front view of FIG. 3, FIG. 5 shows another state of FIG. 4 with the pressure element moved down to the solar cell sheet, and FIG. 6 shows a further state of FIG. 4 with the pressure element moved back up after the solar cell sheet is divided.

As shown in FIG. 1, the division device 1 is used to separate a solar cell sheet 2 into at least two solar cell units 231, 241. A front surface 21 of the solar cell sheet 2 is prepared with a trench 22 extending along a division direction L so as to divide the solar cell sheet 2 into two cut areas 23, 24. Namely, the two solar cell units 231, 241 are originally connected at the trench 22.

The aforesaid trench 22 is formed by, but not limited to, laser cutting. In this embodiment, the front surface 21 is a light receiving surface of the solar cell. In another embodiment, the front surface 21 can be either the light receiving surface of the non-light receiving surface of the solar cell.

As shown in FIG. 1, the division device 1 includes a platform 11, a withstanding element 12, a pressure element 13 and at least one constraint element 14. The platform 11 has a platform surface 111, and the platform surface 111 has a platform trench 1111 extending along the division direction L, so that at least one opening 1112 on the platform surface 111 can be formed along the platform trench 1111.

The withstanding element 12 located on the platform surface 111 has at least one withstanding structure 121 (preferably a shrink-top-type withstanding structure 121) protruding from the platform surface 111 and extending along a withstanding line 100. The withstanding element 12 further has a bottom portion 122 located in the platform trench 1111, and the shrink-top-type withstanding structure 121 extends along the platform trench 1111 and is protrusive over the platform surface 111, such that at least one diamond-shape opening 1112 is formed by integrating the shrink-top-type withstanding structure 121 and the bottom portion 122. In the present invention, the opening 1112 is not limited to the aforesaid diamond shape. In another embodiment, the bottom portion 122 of the withstanding element 12 can be formed to any shape, but the shrink-top-type withstanding structure 121 should be protrusive over the platform surface 111.

In the present invention, the withstanding line 100 is a line segment, as shown in FIG. 2. In this embodiment, the withstanding line 100 is a ridgeline of the shrink-top-type withstanding structure 121. In another embodiment, the division device 1 can include a plurality of shrink-top-type withstanding structures 121, and the withstanding line 100 consists of every individual ridgelines of the shrink-top-type withstanding structures 121. Also, the length of the withstanding line 100 is longer than that of the trench 22 of the solar cell sheet 2, as shown in FIG. 1, such that the trench 22 can be aligned more easily with the withstanding line 100 on the platform surface 111.

In practice, the shrink-top-type withstanding structure 121 is to withstand at a bottom surface of the solar cell sheet 2 that is opposite to a top surface locating the trench 22. Further, the shrink-top-type withstanding structure 121 has a shrink top 1211 keeping a vertical distance (but not limited to) within 0.2-0.4 cm to the platform surface 111. In this embodiment, the shrink top 1211, as the tip portion of the shrink-top-type withstanding structure 121, has a width smaller than the width of the bottom (shown by the dashed line in FIG. 4) of the shrink-top-type withstanding structure 121. In addition, the shrink top 1211 can be either a tip end or a top-shrinking edge, extending along the withstanding line 100. Namely, in a top view, if the withstanding element 12 includes a single shrink-top-type withstanding structure 121, the withstanding element 12 would include only a shrink top 1211. In this circumstance, the shrink top 1211 of this embodiment is the top-shrinking edge extending along the withstanding line 100. On the other hand, if the withstanding element 12 includes a plurality of shrink-top-type withstanding structures 121, then the withstanding element 12 would include a plurality of the shrink tops 1211. At this time, the shrink tops 1211 would be aligned tip ends of tapered structures (a plurality of nodes along the withstanding line 100 in a top view).

The pressure element 13 located above the platform 11 has two forcing portions 131 (one labeled in the figure) protruding toward the platform 11. A top portion of the pressure element 13 (the portion away the platform 11) can be engaged with a power source (a power machine or a human hand). Each of the forcing portions 131 has at least one contact surface 1311 for directly contacting the solar cell sheet 2 on the platform surface 111. In the present invention, the contact surface 1311 can be, but not limited to, a plane, a round surface or any type of surface that can serve the same function.

The aforesaid at least one constraint element 14 (one shown in the figure) is disposed on the platform surface 111 by extending along the two limited lines 200, 300 thereon. In this embodiment, the limited line 200 is perpendicular to the limited line 300 the platform surface 111. The constraint element 14 is consisted of two limited strips 141, 142 extending perpendicularly on the platform surface 111 so as to establish the limited lines 200, 300, respectively. Preferably, the limited strips 141, 142 can be integrated as a unique piece shaped as (but not limited to) an L construction (see FIG. 2).

In another embodiment, other than the two aforesaid limited lines 200, 300, an additional limited line can still exist to provide another directional limit for constraining the solar cell sheet on the platform 11. The protrusive constraint element 14 on the platform surface 111 can be integrated with the platform 11 as a unique piece, or the constraint element 14 and the platform 11 can be connected permanently or temporarily by a connection means. In the art, the permanent connection means can be a welding, an adhesive or any the like. The temporary connection means can be a screw, a bolt, a latch, a pin or any the like. In practice, the determination of the connection means is up to the materials of the constraint element 14 and the platform 11.

The aforesaid at least one constraint element 14 is to provide stops for the solar cell sheet 2 to be positioned correctly on the platform surface 111 while the trench 22 of the solar cell sheet 2 is right to align with the withstanding line 100 of the platform 11. Namely, with two edges of a corner of the solar cell sheet 2 are stopped by the two limited strips 141, 142 of the constraint element 14, then the trench 22 of the solar cell sheet 2 would be correctly aligned with the withstanding line 100 on the platform surface 111.

In the present invention, while the solar cell sheet 2 is under dividing, the back surface 25 of the solar cell sheet 2 is facing the shrink-top-type withstanding structure 121, with the trench 22 on the front surface 21 of the solar cell sheet 2 to align with the withstanding line 100 on the platform surface 111 (the alignment can be ensured by having the solar cell sheet 2 to be stopped by the constraint element 14). Also, the two forcing portions 131 of the pressure element 13 are applied to depress the two cut areas 23, 24 of the solar cell sheet 2. Through the depression applied on the two cut areas 23, 24, the solar cell sheet 2 would be divided into two solar cell units 231, 241, with the trench 22 as the cutting line. In this embodiment, the back surface 25 is the non-light receiving surface of the solar cell. In another embodiment, the back surface 25 can also be the light receiving surface of the solar cell. Note that at least one of the aforesaid back surface 25 and the aforesaid front surface 21 is the light receiving surface.

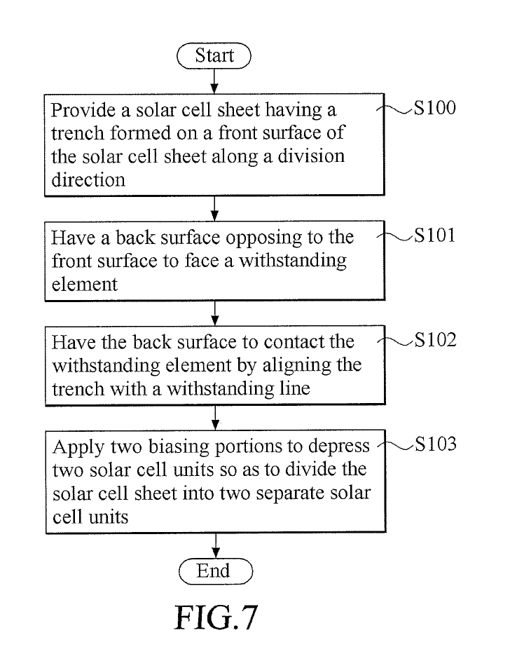

In the present invention, the division method is performed on the aforesaid division device 1. Refer now to FIG. 1 and FIG. 7, where FIG. 7 is a flowchart of a first embodiment of the division method in accordance with the present invention. As shown, the division method includes the following steps.

Step S100: Provide a solar cell sheet 2 having a trench 22 formed on a front surface 21 of the solar cell sheet 2 along a division direction L.

Step S101: Have a back surface 25 of the solar cell sheet 2 that is opposite to the front surface 21 to face a shrink-top-type withstanding structure 121 on a platform surface 111 of a platform 11.

Step S102: Have the back surface 25 of the solar cell sheet 2 to contact the shrink-top-type withstanding structure 121 by aligning the trench 22 with a withstanding line 100 defined by the shrink-top-type withstanding structure 121.

Step S103: Apply two forcing portions 131 down to depress two cut areas 23, 24 on the solar cell sheet 2 so as to divide the solar cell sheet 2 into two separate solar cell units 231, 241.

In this embodiment, Step S100 and Step S101 can be carried out by a machine (a robot arm for example) or by humans. In Step S102, the division device has a constraint element 14 for positioning the solar cell sheet 2 on the platform surface 111. Also, with the constraint element 14 to restrain the movement of the solar cell sheet 2 on the platform surface 111, then while in performing Step S103 to divide the solar cell sheet 2, the trench 22 can be maintained to align with the withstanding line 100. Thereupon, while in moving the two forcing portions 131 of the pressure element 13 downward so as to apply a predetermined depression force F to each of the two cut areas 23, 24 that are joined as a whole (as shown in FIG. 5), then the two original-connected cut areas 23, 24 would be separated into two solar cell units 231, 241, respectively. The aforesaid predetermined force F would be varied according to the materials and structuring of the solar cell sheet 2. A proper force F herein is a force that can only make the solar cell sheet 2 to break along the trench 22, but not to break other portions of the solar cell sheet 2. Namely, with the predetermined force F, the crack on the solar cell sheet 2 would propagate only along the trench 22.

While in applying the predetermined force F, stress concentration along the trench 22 of the solar cell sheet 2 would occurs, such that the solar cell sheet 2 would be cracked only along the trench 22. Preferably, in practice, to determine a relevant magnitude of the force just sufficient to break the solar cell sheet 2 and to propagate the crack only along the trench 22, the forcing upon the solar cell sheet 2 is gradually increased till the predetermined force F is achieved to divide the solar cell sheet 2 perfectly. Namely, by applying the predetermined force F to the solar cell sheet 2, the crack to divide the solar cell sheet 2 would be only limited to propagate along the trench 22. Thereupon, all the areas of the solar cell sheet 2 other than the trench 22 would be free from any crack.

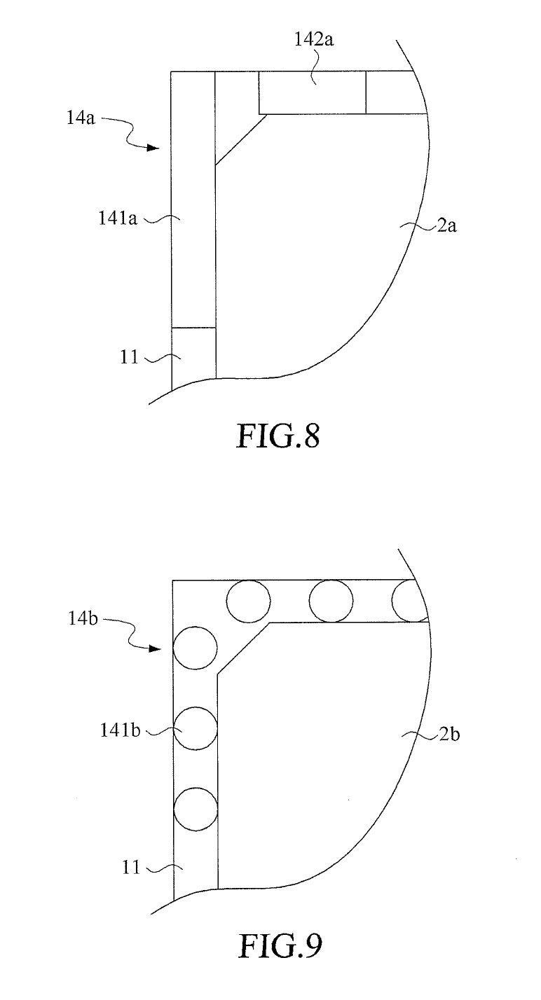

Referring now to FIG. 8, a schematic top view of a constraint element of a second embodiment of the division device in accordance with the present invention is shown. In this second embodiment, the major difference with respect to the aforesaid first embodiment is that the limited strips 141a and 142a of the constraint element 14a are not connected, but still distributed along the corresponding limited lines (not shown in the figure) for contacting the edges of the solar cell sheet 2a.

Referring now to FIG. 9, a schematic top view of a constraint element of a third embodiment of the division device in accordance with the present invention is shown. In this third embodiment, the major difference with respect to the aforesaid first embodiment is that the constraint element 14b includes a plurality of limited posts 141b (one labeled in the figure) distributed along the two corresponding limited lines (not shown in the figure) for contacting the edges of the solar cell sheet 2b.

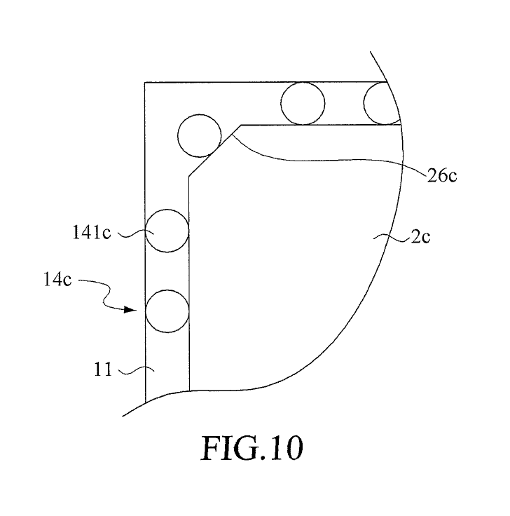

Referring now to FIG. 10, a schematic top view of a constraint element of a fourth embodiment of the division device in accordance with the present invention is shown. In this fourth embodiment, the major difference with respect to the aforesaid third embodiment is that the constraint element 14c is consisted of plural limited posts 141c, and at least one of the limited posts 141c contacts the corner 26c of the solar cell sheet 2c, namely the chamfered edge of the solar cell sheet 2c.

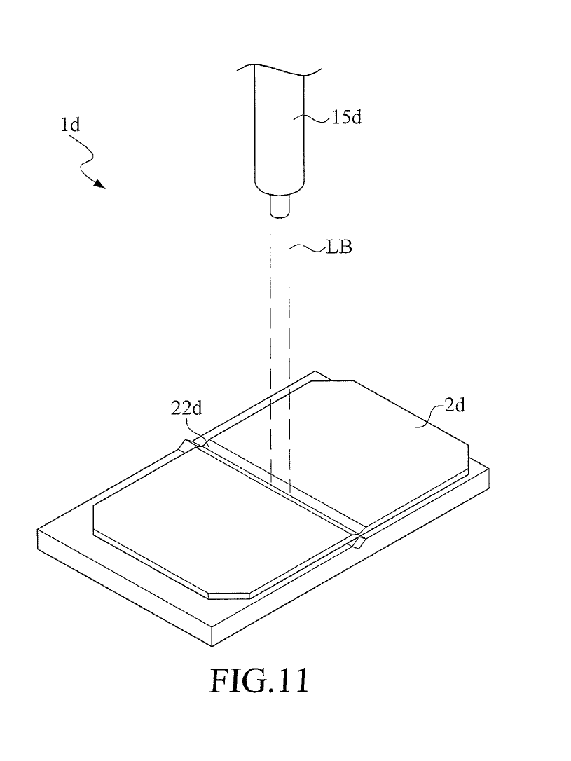

Referring now to FIG. 11, a schematic top view of a fifth embodiment of the division device in accordance with the present invention is shown. In this embodiment, the division device 1d is not furnished with a constraint element, but includes an alignment device 15d. The alignment device 15d can be a non-contact optical alignment device, such as a light-emitting device, an image-capturing device or a combination of the light-emitting device and the image-capturing device. In this fourth embodiment, the alignment device 15d is embodied as an image-capturing device for aligning the trench 22d with the withstanding line (not shown in the figure). In the aligning, the alignment device 15d would project a light beam B onto the solar cell sheet 2 and the division device 1d. Then, images of the trench 22d and the withstanding line would be captured by the alignment device 15d for alignment comparison. Typically, the alignment judgment would depend on whether or not the withstanding line is overlapped with the trench 22d of the solar cell sheet 2 at the both opposing ends of the trench 22d. If the withstanding line is not collinear with the trench 22d in a top view from the alignment device 15d, “non-aligned” is judged. Then, the solar cell sheet 2 would be moved accordingly for further alignment investigation, until the alignment device 15d determines that the withstanding line is collinear with the trench 22d. In the present invention, this alignment investigation by the alignment device 15d can be carried out in the aforesaid Step S103.

In another embodiment, the non-contact optical alignment device includes a light-emitting module and an image-capturing module, disposed to opposing sides of the solar cell sheet 2. The light-emitting module would emit the light beam from one side (either the side close to the front surface 21 or the side close to the back surface 25), so as to generate an image of the solar cell sheet 2 to be captured by the image-capturing module at the other side. By compared the captured image of the instant solar cell sheet 2 on the platform 11 with a reference image of an accurate-positioned solar cell sheet pre-stored in a memory unit, then positioning bias of the solar cell sheet 2 can be determined. In the case that a bias in position of the solar cell sheet 2 on the platform 11 is determined, re-aligning of the trench 22 of the solar cell sheet 2 with the withstanding line 100 on the platform surface 111 is necessary.

In summary, by providing the aforesaid division device and method in accordance with the present invention, the back surface of the solar cell sheet is introduced to contact directly the shrink-top-type withstanding structure by aligning the trench with the withstanding line, and the pressure element is applied to depress directly and divide perfectly the solar cell sheet, such that tedious working procedures in the conventional division method can be avoided, and thus process time and cost can be substantially reduced.

While the present invention has been particularly shown and described with reference to a preferred embodiment, it will be understood by those skilled in the art that various changes in form and detail may be without departing from the spirit and scope of the present invention.

What is claimed is:

1. A division device, being to divide a solar cell sheet into two solar cell units, the solar cell sheet having a front surface prepared with a trench extending along a division direction, the two solar cell units being connected at the trench, the division device comprising:
a platform, having a platform surface;
a withstanding element, located on the platform surface, having at least one shrink-top-type withstanding structure protruding from the platform surface and extending along a withstanding line, the shrink-top-type withstanding structure being to withstand the solar cell sheet; and
a pressure element, located above the platform, having two forcing portions protruding toward the platform;
wherein, while the solar cell sheet is under dividing, a back surface of the solar cell sheet opposing to the front surface is arranged to face the shrink-top-type withstanding structure by aligning the trench with the withstanding line, and then the two forcing portions are introduced to apply predetermined depression individually onto the two solar cell units, such that the solar cell sheet are divided into the two separate solar cell units.

2. The division device of claim 1, wherein the shrink-top-type withstanding structure has a shrink top keeping a vertical distance within 0.2-0.4 cm to the platform surface.

3. The division device of claim 2, wherein the shrink top is one of a tip end and a top-shrinking edge, extending along the withstanding line.

4. The division device of claim 1, wherein the platform surface has a platform trench extending along the division direction, so that at least one opening is formed on the platform surface.

5. The division device of claim 4, wherein the withstanding element further has a bottom portion located in the platform trench, the shrink-top-type withstanding structure extending along the platform trench and being protrusive over the platform surface.

6. The division device of claim 1, wherein a length of the withstanding line is longer than that of the trench of the solar cell sheet.

7. The division device of claim 1, wherein the solar cell sheet division device further includes at least one constraint element disposed on the platform surface; wherein, while the solar cell sheet is under dividing, the at least one constraint element limits the solar cell sheet so as to ensure the trench aligned with the withstanding line.

8. The division device of claim 7, wherein the at least one constraint element is disposed on the platform surface by extending along two limited lines; while the solar cell sheet is under dividing, the at least one constraint element withstands two edges of the solar cell sheet.

9. The division device of claim 8, wherein the constraint element includes two limited strips extending to establish the two limited lines.

10. The division device of claim 8, wherein the constraint element includes a plurality of limited posts separately disposed along the two limited lines.

11. A division method for dividing a solar cell sheet, applied to the division device of claim 1, comprising the steps of:
(a) providing the solar cell sheet of claim 1, the solar cell sheet having the trench formed on the front surface of the solar cell sheet along the division direction;
(b) having the back surface of the solar cell sheet to face the shrink-top-type withstanding structure;
(c) having the back surface to contact the shrink-top-type withstanding structure by aligning the trench with the withstanding line defined by the shrink-top-type withstanding structure; and
(d) applying the two forcing portions down to depress the two solar cell units of the solar cell sheet so as to divide the solar cell sheet into the two separate solar cell units.

12. The division method of claim 11, wherein the solar cell sheet division device further includes at least one constraint element disposed on the platform surface; wherein, in performing step (c) and step (d), the at least one constraint element limits the solar cell sheet so as to ensure the trench aligned with the withstanding line.

13. The division method of claim 11, wherein, in step (c), an alignment device is applied to ensure the trench aligned with the withstanding line.

14. The division method of claim 13, wherein the alignment device is a non-contact optical alignment device.

15. The division method of claim 14, wherein the non-contact optical alignment device is one of a light-emitting device, an image-capturing device, and a combination of the light-emitting device and the image-capturing device.
